(19) United States
(12) Patent Application Publication
(10) Pub. No.: US 2022/0415838 A1
(43) Pub. Date: Dec. 29, 2022

(54) SEMICONDUCTOR PACKAGE AND METHOD OF FABRICATING THE SAME

(71) Applicant: SAMSUNG ELECTRONICS CO., LTD., SUWON-SI (KR)

(72) Inventor: SANGJIN LEE, Incheon (KR)

(21) Appl. No.: 17/649,217

(22) Filed: Jan. 28, 2022

(30) Foreign Application Priority Data
Jun. 29, 2021 (KR) 10-2021-0084710

(51) Int. Cl. H01L 23/00

(52) U.S. Cl. CPC H01L 24/19; H01L 24/16; H01L 24/20; H01L 24/24; H01L 24/73; H01L 2224/73259; H01L 2224/16235; H01L 2224/19; H01L 2224/24151; H01L 2224/221; H01L 25/105

(57) ABSTRACT

Disclosed are semiconductor packages and their fabricating methods. The method includes preparing a semiconductor chip with a pillar pattern on a bottom surface thereof, placing the semiconductor chip side by side with a connection substrate with a conductive pad on a bottom surface thereof, forming a molding layer on the bottom surfaces of the connection substrate and the semiconductor chip to cover the pillar pattern and the conductive pad, forming a first redistribution substrate on top surfaces of the connection substrate, the semiconductor chip, and the molding layer and directly in physical contact with the top surface of the semiconductor chip, and performing a grinding process on a bottom surface of the molding layer to expose the pillar pattern and the conductive pad. An outer sidewall of the connection substrate is vertically aligned with that of the first redistribution substrate.

### CROSS-REFERENCE TO RELATED APPLICATION

This U.S. nonprovisional application claims priority under 35 U.S.C. § 119 to Korean Patent Application No. 10-2021-0084710, filed on Jun. 29, 2021, in the Korean Intellectual Property Office, the disclosure of which is incorporated by reference herein in its entirety.

### TECHNICAL FIELD

The present inventive concept relates to a semiconductor package, and more particularly, to a semiconductor package including a redistribution substrate and a method of fabricating the same.

### DISCUSSION OF RELATED ART

A semiconductor package is provided to implement an integrated circuit chip in such a way that it is suitable or ideal for use in electronic products. For example, the semiconductor package may be configured such that a semiconductor chip is mounted on a printed circuit board and bonding wires or bumps are used to electrically connect the semiconductor chip to the printed circuit board. With the advance of electronics industry, an advanced semiconductor package having higher and faster performance in a thinner and smaller form factor may be desirable. However, miniaturization in semiconductor packaging without degrading the thermal, electrical and/or mechanical properties of the semiconductor chip is a challenge. Therefore, various studies have been conducted to enhance reliability and durability of semiconductor packages.

### SUMMARY

Example embodiments of the present inventive concept provide a semiconductor package with increased reliability and enhanced thermal properties and a method of fabricating the same.

Example embodiments of the present inventive concept provide a simplified method of fabricating a semiconductor package, and the method has increased accuracy.

According to an example embodiment of the present inventive concept, a method of fabricating a semiconductor package includes: preparing a semiconductor chip provided with a pillar pattern on a bottom surface of the semiconductor chip; placing the semiconductor chip side by side with a connection substrate provided with a conductive pad on a bottom surface of the connection substrate; forming a molding layer on the bottom surface of the connection substrate and on the bottom surface of the semiconductor chip to cover the pillar pattern and the conductive pad; forming a first redistribution substrate on a top surface of the connection substrate, a top surface of the semiconductor chip, and a top surface of the molding layer, the first redistribution substrate being directly in physical contact with the top surface of the semiconductor chip; and performing a grinding process on a bottom surface of the molding layer to expose the pillar pattern and the conductive pad. An outer sidewall of the connection substrate may be vertically aligned with an outer sidewall of the first redistribution substrate.

According to an example embodiment of the present inventive concept, a method of fabricating a semiconductor package includes: preparing a semiconductor chip provided with a bump on a bottom surface of the semiconductor chip, the bump including a pillar pattern; placing the semiconductor chip side by side with a connection substrate provided with a conductive pad on a bottom surface of the connection substrate; forming a molding layer on the bottom surface of the connection substrate and on the bottom surface of the semiconductor chip to cover the bump and the conductive pad; forming a first redistribution substrate in physical contact with a top surface of the connection substrate, a top surface of the semiconductor chip, and a top surface of the molding layer; and performing a grinding process on a bottom surface of the molding layer to expose the pillar pattern and the conductive pad. The connection substrate may include a plurality of connection pads on the top surface of the connection substrate. The step of forming the first redistribution substrate may include: forming a first seed pattern directly coupled to each of the connection pads; and forming a first redistribution pattern on the first seed pattern.

According to an example embodiment of the present inventive concept, a method of fabricating a semiconductor package includes: preparing a semiconductor chip provided with a bump on a bottom surface of the semiconductor chip, the bump including a pillar pattern; preparing a connection substrate provided with a conductive pad on a bottom surface of the connection substrate, the connection substrate having a hole that penetrates the connection substrate; placing the semiconductor chip and the connection substrate on a bottom surface of a temporary tape, the semiconductor chip being in the hole of the connection substrate and being in physical contact with the bottom surface of the temporary tape; forming a molding layer on the bottom surface of the connection substrate and on the bottom surface of the semiconductor chip to cover a bottom surface of the bump and a bottom surface of the conductive pad, the molding layer extending between the connection substrate and the semiconductor chip and physically contacting the temporary tape; removing the temporary tape to expose a top surface of the connection substrate, a top surface of the semiconductor chip, and a top surface of the molding layer; forming a first redistribution substrate on the top surface of the connection substrate, the top surface of the semiconductor chip, and the top surface of the molding layer, the first redistribution substrate being directly in physical contact with the top surface of the semiconductor chip; performing a grinding process on a bottom surface of the molding layer to expose the pillar pattern and the conductive pad; forming a second redistribution substrate on the exposed pillar pattern and the exposed conductive pad; and forming a solder ball on a bottom surface of the second redistribution substrate.

According to an example embodiment of the present inventive concept, a semiconductor package includes: a lower redistribution substrate that includes a lower seed pattern and a lower redistribution pattern on a bottom surface of the lower seed pattern; a semiconductor chip disposed on the lower redistribution substrate; a pillar pattern disposed between the lower redistribution substrate and the semiconductor chip and being in direct contact with the lower seed pattern; a connection substrate disposed on the lower redistribution substrate and laterally spaced apart from the semiconductor chip; an upper redistribution substrate disposed on the semiconductor chip and the connection substrate and being in direct contact with a top surface of the semiconductor chip; and a molding layer disposed between the lower redistribution substrate and the upper redistribution substrate and between the semiconductor chip and the connection substrate. An outer sidewall of the connection substrate may be vertically aligned with an outer sidewall of the lower redistribution substrate and with an outer sidewall of the upper redistribution substrate. The connection substrate may include a connection pad on a top surface of the connection substrate. The upper redistribution substrate may include: an upper seed pattern being in direct contact with the connection pad; and an upper redistribution pattern disposed on the upper seed pattern.

### BRIEF DESCRIPTION OF THE DRAWINGS

Example embodiments of the present inventive concept will be more clearly understood from the following detailed description taken in conjunction with the accompanying drawings in which:

FIG. 1 illustrates a plan view showing a semiconductor package according to an example embodiment of the present inventive concept;

FIGS. 2A to 2M illustrate cross-sectional views showing a method of fabricating a semiconductor package according to an example embodiment of the present inventive concept;

FIG. 3 illustrates a cross-sectional view showing a method of fabricating a semiconductor package according to an example embodiment of the present inventive concept;

FIGS. 4A to 4D illustrate cross-sectional views showing a method of fabricating a semiconductor package according to an example embodiment of the present inventive concept;

FIG. 5 illustrates a cross-sectional view showing a semiconductor package according to an example embodiment of the present inventive concept; and

FIG. 6 illustrates a cross-sectional view showing a semiconductor package according to an example embodiment of the present inventive concept.

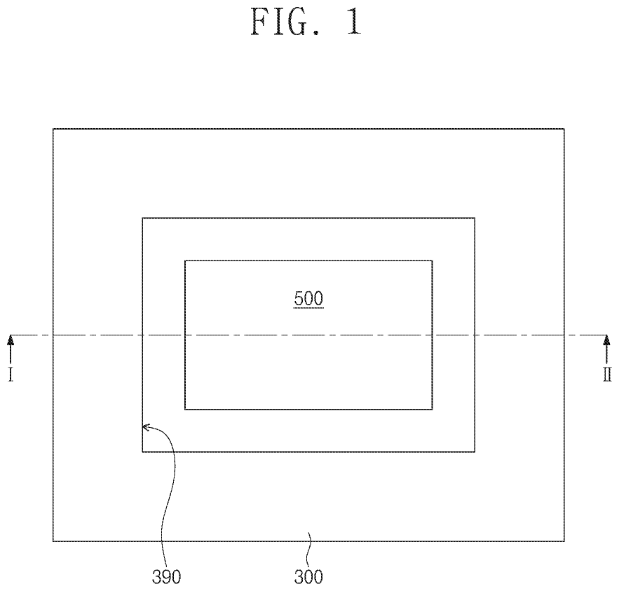

Since the drawings in FIGS. 1-6 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

In this description, like reference numerals may indicate like components. The following will now describe semiconductor packages and their fabricating methods according to example embodiments of the present inventive concept.

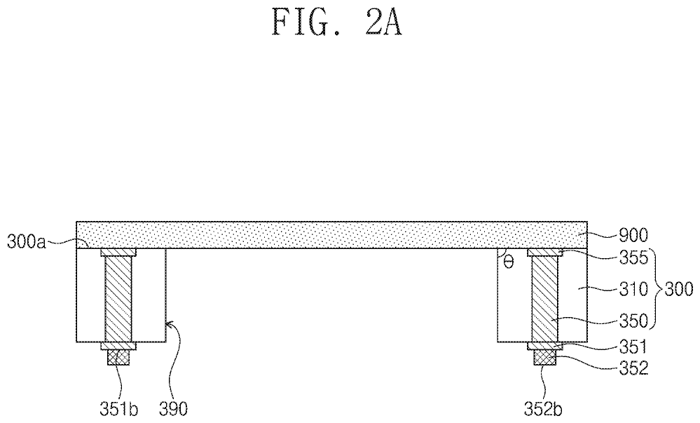

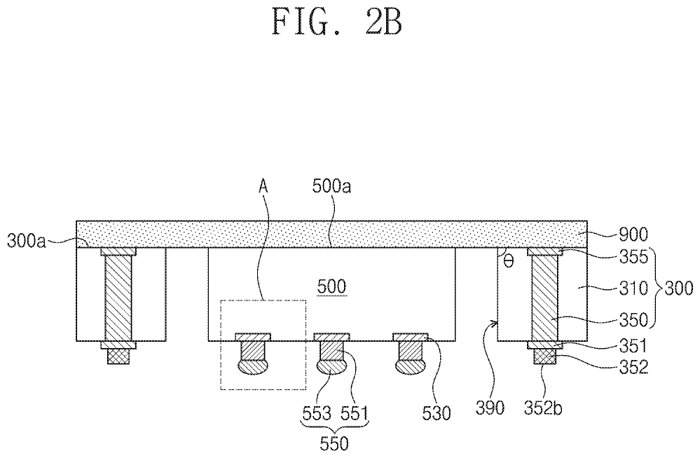

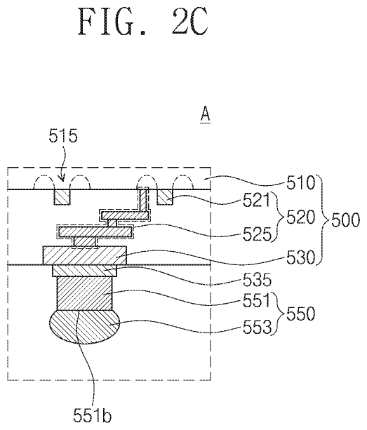

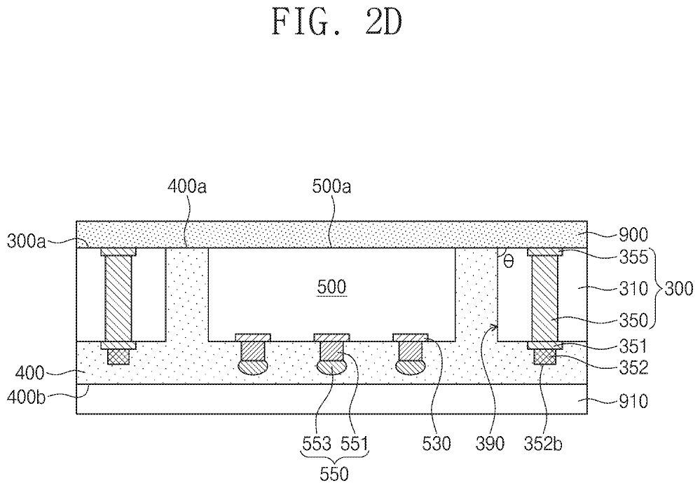

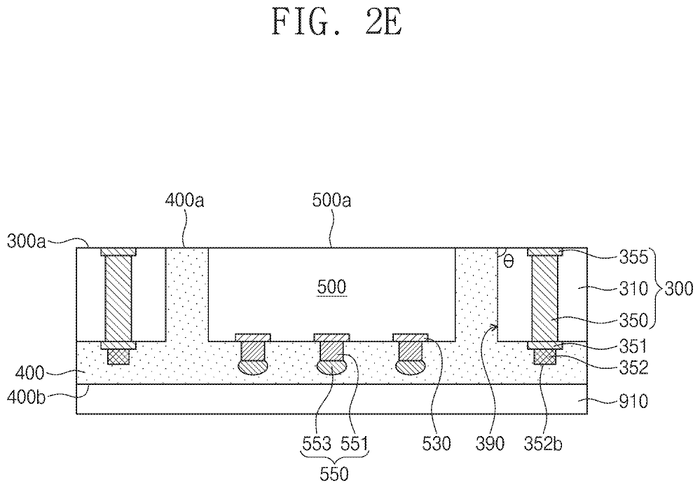

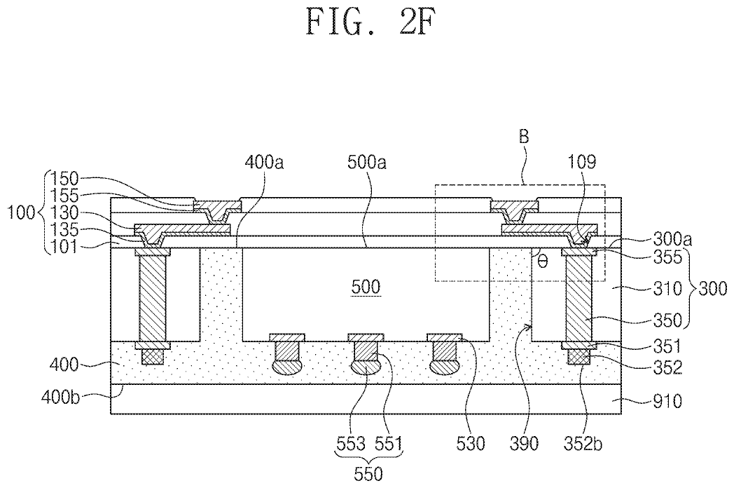

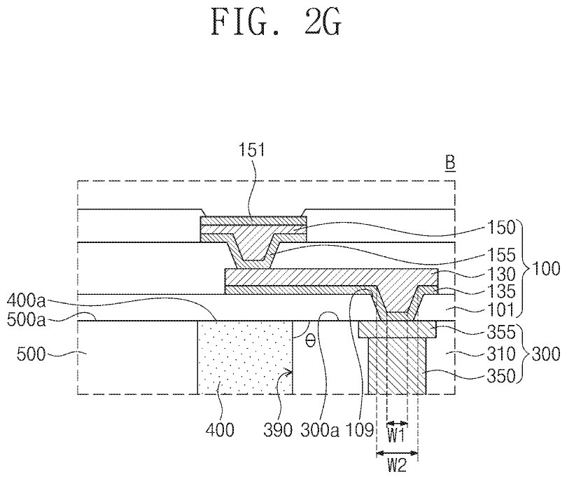

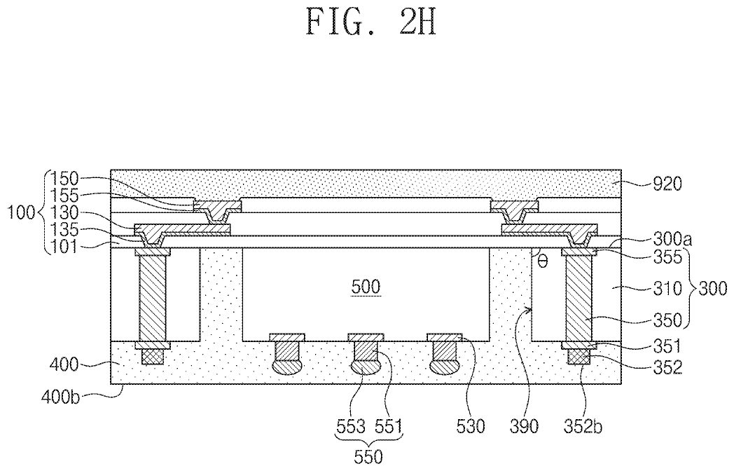

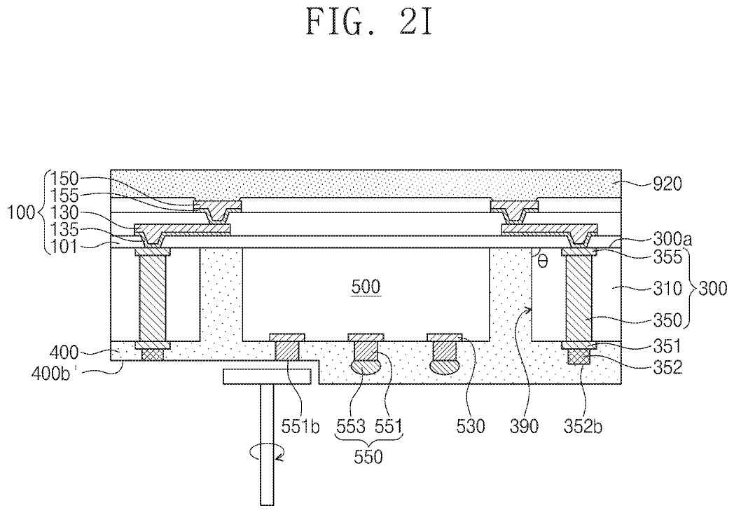

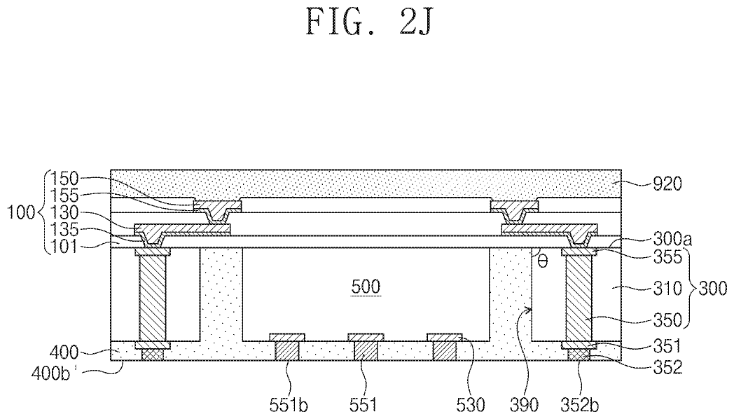

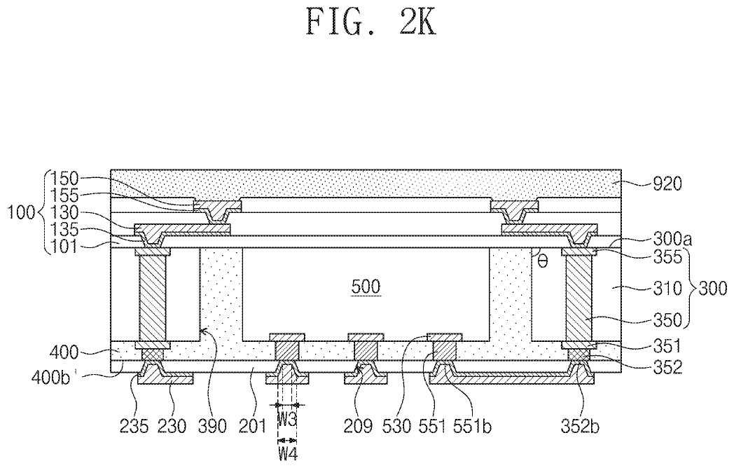

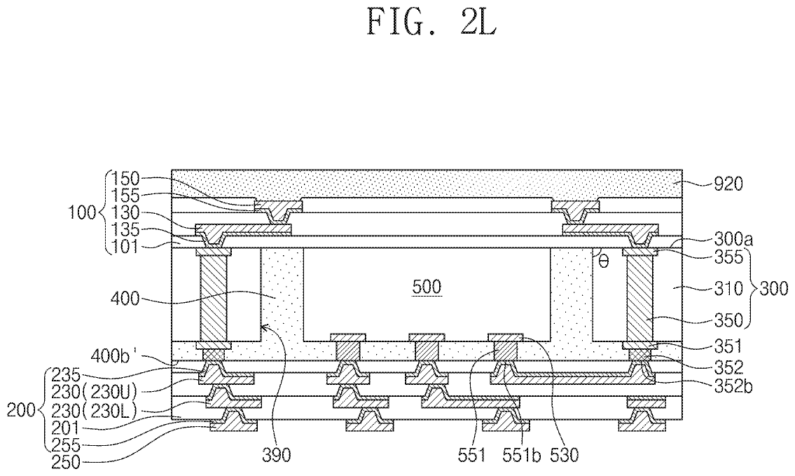

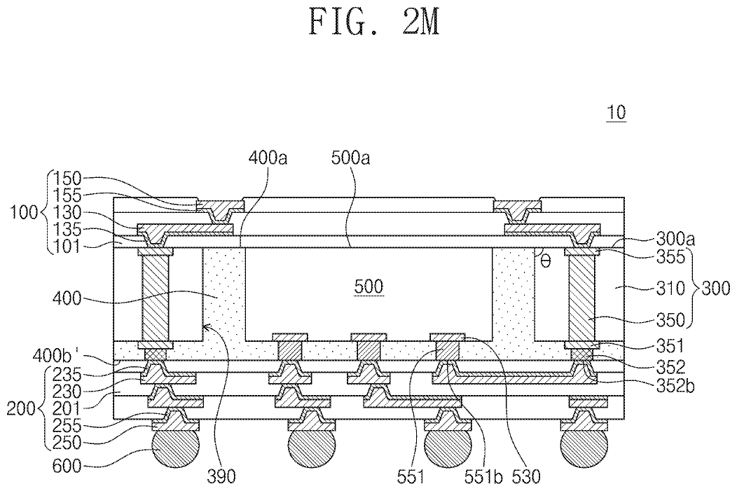

FIG. 1 illustrates a plan view showing a semiconductor package according to an example embodiment of the present inventive concept. FIGS. 2A, 2B, 2D to 2F, and 2H to 2M illustrate cross-sectional views taken along line I-II of FIG. 1, showing a method of fabricating a semiconductor package according to an example embodiment of the present inventive concept. FIG. 2C illustrates an enlarged view showing section A of FIG. 2B. FIG. 2G illustrates an enlarged view showing section B of FIG. 2F.

Referring to FIGS. 1 and 2A, a connection substrate 300, which is provided with a conductive pad, may be prepared. The connection substrate 300 may have a top surface 300a and a bottom surface that face each other. The connection substrate 300 may be, for example, an embedded trace substrate. For example, the connection substrate 300 may have a hole 390. The hole 390 of the connection substrate 300 may penetrate the top surface 300a and the bottom surface of the connection substrate 300. For example, the hole 390 may be formed in a printed circuit board (PCB), and the printed circuit board having the hole 390 may be used as the connection substrate 300. Only one hole 390 is shown in FIG. 1, but the present inventive concept is not limited thereto. For example, in an example embodiment of the present inventive concept, the connection substrate 300 may have a plurality of holes. In other words, the connection substrate 300 may have multiple holes to accommodate multiple components. For example, at least one of the components may be a semiconductor chip 500 to be described. The hole 390 of the connection substrate 300 may expose an inner sidewall of the connection substrate 300. For example, the inner sidewall of the connection substrate 300 may be a sidewall of the hole 390. When viewed in plan, the hole 390 may be formed on a central portion of the connection substrate 300. A laser may be used to form the hole 390. Alternatively, the hole 390 may be formed by, for example, a mechanical drilling process, a sandblasting process, or a dry etching process using plasma. Therefore, an angle θ between the top surface 300a and the inner sidewall of the connection substrate 300 may range from about 85 degrees to about 95 degrees. An angle between the bottom surface and the inner sidewall of the connection substrate 300 may range from about 85 degrees to about 95 degrees. The term “about” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

The connection substrate 300 may include a base layer 310, a connection via 350, and a connection pad 355. The base layer 310 may include a dielectric material. For example, the base layer 310 may include a ceramic, a silicon-based dielectric material, or a dielectric polymer. The connection via 350 may be provided in the base layer 310, and may be a metal pillar. The connection pad 355 may be disposed on a top surface of the connection via 350 and may be exposed on the top surface 300a of the connection substrate 300. For example, the top surface of the connection via 350 may be a part of the top surface 300a of the connection substrate 300. The connection via 350 may extend from the connection pad 355 to the bottom surface of the connection substrate 300. The connection via 350 and the connection pad 355 may include metal, such as one or more of, for example, copper (Cu), aluminum (Al), tungsten (W), titanium (Ti), tantalum (Ta), iron (Fe), and any alloy thereof.

The conductive pad may include a first conductive pad 351 and a second conductive pad 352. The first conductive pad 351 may be provided on the bottom surface of the connection substrate 300. For example, the first conductive pad 351 may be provided on a bottom surface of the connection via 350 and may be coupled to the connection via 350. The first conductive pad 351 may be a component of a printed circuit board, but the present inventive concept is not limited thereto. The second conductive pad 352 may be provided on a bottom surface 351b of the first conductive pad 351. For example, the first conductive pad 351 may be interposed between the connection via 350 and the second conductive pad 352. The second conductive pad 352 may have a width less than that of the first conductive pad 351. The second conductive pad 352 may be coupled to the connection pad 355 through the first conductive pad 351 and the connection via 350. The first conductive pad 351 and the second conductive pad 352 may include metal, such as one or more of, for example, copper (Cu), aluminum (Al), tungsten (W), titanium (Ti), tantalum (Ta), and any alloy thereof.

The connection substrate 300 may be disposed on a bottom surface of a temporary tape 900. For example, the top surface 300a of the connection substrate 300 may be directly attached to the bottom surface of the temporary tape 900. The temporary tape 900 may cover the entire top surface 300a of the connection substrate 300 and the entire hole 390. Alternatively, the temporary tape 900 may cover the entire hole 390 and a portion of the connection substrate 300. The temporary tape 900 may include a dielectric polymer, such as polyimide. The temporary tape 900 may be an adhesion tape. Alternatively, the temporary tape 900 may further include an adhesive coated on the bottom surface thereof. Therefore, no adhesion layer may be separately provided between the temporary tape 900 and the connection substrate 300.

Referring to FIGS. 1, 2B, and 2C, a semiconductor chip 500, which is provided with bumps 550, may be prepared. The semiconductor chip 500 may have a top surface 500a and a bottom surface that face each other. As shown in FIG. 2C, the semiconductor chip 500 may include a semiconductor substrate 510, integrated circuits 515, a wiring layer 520, and a chip pad 530. The semiconductor substrate 510 may include, for example, a silicon (Si) substrate, a germanium (Ge) substrate, or a silicon-germanium (SiGe) substrate. The top surface 500a of the semiconductor chip 500 may correspond to a top surface of the semiconductor substrate 510. The top surface of the semiconductor substrate 510 may be a rear surface, and a bottom surface of the semiconductor substrate 510 may be a front surface. The integrated circuits 515 may be provided on the bottom surface of the semiconductor substrate 510. The integrated circuits 515 may include, for example, transistors. The transistors may be, for example, metal oxide semiconductor field effect transistors (MOSFET), complementary metal oxide semiconductor (CMOS) transistors, bipolar junction transistors (BJT), or insulated-gate bipolar transistors (IGBTs), but the present inventive concept is not limited thereto. The wiring layer 520 may be disposed on the bottom surface of the semiconductor substrate 510, and may include a dielectric pattern 521 and a wiring structure 525. On the bottom surface of the semiconductor substrate 510, the dielectric pattern 521 may cover the transistors. The dielectric pattern 521 may include a multiple layer. The wiring structure 525 may be provided in a dielectric layer. The dielectric layer may be formed of an oxide layer and/or a nitride layer. The wiring structure 525 may include metal, such as one or more of, for example, copper (Cu), titanium (Ti), and tungsten (W). A plurality of chip pads 530 may be disposed on a bottom surface of the wiring layer 520. The chip pads 530 may include metal, such as one or more of, for example, copper (Cu), aluminum (Al), and any alloy thereof. The chip pads 530 may be coupled through the wiring structure 525 to the integrated circuits 515. The phrase “a certain component is electrically connected to the semiconductor chip 500” may mean that a certain component is electrically connected through the chip pads 530 of the semiconductor chip 500 to the integrated circuits 515 of the semiconductor chip 500. The bottom surface of the semiconductor chip 500 may correspond to that of the wiring layer 520 and that of the chip pad 530. The semiconductor chip 500 may be, for example, a memory chip, an application processor chip, or a logic chip, but the present inventive concept is not limited thereto.

The bumps 550 may be provided on the bottom surface of the semiconductor chip 500. For example, the bumps 550 may be correspondingly provided on the bottom surfaces of the chip pads 530. Each of the bumps 550 may include a pillar pattern 551 and a solder pattern 553. The pillar patterns 551 may be correspondingly provided on the bottom surfaces of the chip pads 530, thereby being coupled to the chip pads 530. For example, the chip pads 530 may be provided to electrically connect the semiconductor chip 500 to other components, for example, to an external power source. Each of the pillar patterns 551 may have a cylindrical shape. The pillar patterns 551 may include metal, such as, for example, copper (Cu).

The solder patterns 553 may be correspondingly disposed on bottom surfaces 551b of the pillar patterns 551, thereby being coupled to the pillar patterns 551. The solder patterns 553 may include a material different from that of the pillar patterns 551. For example, the solder pattern 553 may include one or more of, for example, tin (Sn), silver (Ag), zinc (Zn), lead (Pb), and any alloy thereof. The bumps 550 may have their bottom surfaces that correspond to those of the solder patterns 553.

As shown in FIG. 2C, an under-bump pattern 535 may further be interposed between the bump 550 and the chip pad 530. Alternatively, the under-bump pattern 535 may be omitted, and a plurality of pillar patterns 551 may be directly coupled to corresponding chip pads 530. In figures except for FIG. 2C, the illustration of the under-bump pattern 535 is omitted for brevity. The present inventive concept, however, is not intended to exclude the under-bump pattern 535.

As shown in FIGS. 1 and 2B, the semiconductor chip 500 may be provided within the hole 390 of the connection substrate 300 and may be disposed laterally spaced apart from the connection substrate 300. For example, the semiconductor chip 500 may be placed side by side with the connection substrate 300. The phrase “certain components are disposed laterally of each other” may mean that certain components are disposed horizontally to each other. The term “horizontally” may indicate “parallel to the top surface 500a of the semiconductor chip.” The semiconductor chip 500 may be disposed on the bottom surface of the temporary tape 900. For example, the top surface 500a of the semiconductor chip 500 may be directly attached to the bottom surface of the temporary tape 900. When an adhesion layer is separately interposed between the semiconductor chip 500 and the temporary tape 900, the semiconductor chip 500 may lean or move due to fluidity of the adhesion layer in a curing process of the adhesion layer. Alternatively, a void may be formed between the adhesion layer and the semiconductor chip 500 in a curing process of the adhesion layer. According to an example embodiment of the present inventive concept, the top surface 500a of the semiconductor chip 500 may be in physical contact with the bottom surface of the temporary tape 900, and no adhesion layer may be separately provided between the temporary tape 900 and the semiconductor chip 500. For example, the temporary tape 900 is allowed to be directly attached to the semiconductor chip 500 and the connection substrate 300 in the process of placing the semiconductor chip 500 on the bottom surface of the temporary tape 900. Therefore, the semiconductor chip 500 may be prevented from moving and leaning. There may occur an increase in accuracy of a semiconductor package fabricating method. In addition, the formation and curing of a separate adhesion layer may be omitted to simplify the semiconductor package fabricating method. The occurrence of void may be prevented between the semiconductor chip 500 and the temporary tape 900.

The top surface 500a of the semiconductor chip 500 may be located at a level substantially the same as that of the top surface 300a of the connection substrate 300. In this description, the term of level may indicate a vertical level, and a level difference may be measured in a direction perpendicular to the top surface 500a of the semiconductor chip 500. The phrase “certain components are the same in terms of level, thickness, or length” may include an allowable tolerance possibly occurring during fabrication process.

When the inner sidewall of the connection substrate 300 is excessively inclined relative to the top surface 300a of the connection substrate 300, there may be a limitation on a space where the semiconductor chip 500 is disposed. The excessively inclined inner sidewall of the connection substrate 300 may reduce the size of the hole 390 either on the top surface or on the bottom surface. For example, when the angle θ between the inner sidewall and the top surface 300a of the connection substrate 300 is less than about 85 degrees or greater than about 95 degrees, there may be a limitation on a space where the semiconductor chip 500 is disposed. According to an example embodiment of the present inventive concept, as the angle θ between the inner sidewall and the top surface 300a of the connection substrate 300 is in a range from about 85 degrees to about 95 degrees, a width at an upper portion of the hole 390 may be the same as or similar to that at a lower portion of the hole 390. Therefore, the semiconductor chip 500 may be satisfactorily accommodated in the hole 390.

Referring to FIG. 2D, a molding layer 400 may be formed on the bottom surface of the connection substrate 300 and on the bottom surface of the semiconductor chip 500. The formation of the molding layer 400 may include attaching an adhesive dielectric film onto the bottom surface of the connection substrate 300 and onto the bottom surface of the semiconductor chip 500. For example, an Ajinomoto build-up film (ABF) may be used as the adhesive dielectric film. However, the present inventive concept is not limited thereto. For example, any other suitable thermosetting resin or thermoplastic resin may be used as the adhesive dielectric film. For example, a photosensitive insulating material may be used as the adhesive dielectric film. The molding layer 400 may cover a bottom surface 352b of the second conductive pad 352 and the bottom surfaces of the bumps 550. The molding layer 400 may have a bottom surface 400b located at a level lower than that of the bottom surface 352b of the second conductive pad 352 and that of the bottom surfaces of the bumps 550. The molding layer 400 may extend into a gap between the connection substrate 300 and the semiconductor chip 500, thereby contacting the bottom surface of the temporary tape 900. For example, the molding layer 400 may fill the gaps between the connection substrate 300 and the semiconductor chip 500, and may cover the side surfaces of the semiconductor chip 500 and the inner sidewalls of the connection substrate 300. For example, the molding layer 400 may have a top surface 400a in physical contact with the bottom surface of the temporary tape 900. The top surface 400a of the molding layer 400 may be coplanar with the top surface 300a of the connection substrate 300 and with the top surface 500a of the semiconductor chip 500. For example, the top surface 400a of the molding layer 400 may be located at a level substantially the same as that of the top surface 300a of the connection substrate 300 and that of the top surface 500a of the semiconductor chip 500.

The first conductive pads 351, the second conductive pads 352, the pillar patterns 551 and the solder patterns 553 may be completely surrounded by the molding layer 400. Even when a process error causes the molding layer 400 to partially flow between the semiconductor chip 500 and the temporary tape 900, because the solder patterns 553 are disposed on the bottom surface of the semiconductor chip 500, no effect may be produced on electrical connection of the semiconductor chip 500.

Differently from that shown, the molding layer 400 may have an undulation on the bottom surface 400b thereof. For example, a bottom surface at a first part of the molding layer 400 may be located at a level different from that of a bottom surface at a second part of the molding layer 400. For example, the first part of the molding layer 400 may be disposed on the bottom surface of the semiconductor chip 500 or on the bottom surface of the connection substrate 300. The second part of the molding layer 400 may be provided in the gap between the connection substrate 300 and the semiconductor chip 500. In an example embodiment of the present inventive concept, one or both of the first part and the second part may not be flat. For example, the first part of the molding layer 400 may be convex downward with the central portion bent away from the temporary tape 900, and/or the second part of the molding layer 400 may be concave downward with the central portion bent toward the temporary tape 900. Alternatively, the molding layer 400 may have no undulation on the bottom surface 400b thereof.

A first carrier substrate 910 may be disposed on the bottom surface 400b of the molding layer 400. A first carrier adhesion layer may further be interposed between the first carrier substrate 910 and the molding layer 400.

Referring to FIG. 2E, the temporary tape 900 may be removed to expose the top surface 300a of the connection substrate 300, the top surface 400a of the molding layer 400, and the top surface 500a of the semiconductor chip 500. To remove the temporary tape 900, the temporary tape 900 may be subjected to a heat treatment or a radiation treatment to weaken the adhesion between the temporary tape 900 and the assembly including the connection substrate 300, the molding layer 400 and the semiconductor chip 500.

Referring to FIGS. 2F and 2G, a first redistribution substrate 100 may be formed on the exposed top surface 300a of the connection substrate 300, the exposed top surface 400a of the molding layer 400, and the exposed top surface 500a of the semiconductor chip 500. For example, the first redistribution substrate 100 may be directly in physical contact with the top surface 300a of the connection substrate 300, the top surface 500a of the semiconductor chip 500, and the top surface 400a of the molding layer 400. The first redistribution substrate 100 may be an upper redistribution substrate. The first redistribution substrate 100 may include a first dielectric layer 101, a first redistribution pattern 130, a first seed pattern 135, a first redistribution pad 150, and a first seed pad 155. When the first redistribution substrate 100 is an upper redistribution substrate, the first redistribution pattern 130 may be an upper redistribution pattern and the first seed pattern 135 may be an upper seed pattern.

The first dielectric layer 101 may be formed on the connection substrate 300, the molding layer 400, and the semiconductor chip 500, thereby covering the top surface 300a of the connection substrate 300, the top surface 400a of the molding layer 400, and the top surface 500a of the semiconductor chip 500. For example, the first dielectric layer 101 may be in direct contact with the top surface 300a of the connection substrate 300, the top surface 400a of the molding layer 400, and the top surface 500a of the semiconductor chip 500. The first dielectric layer 101 may have a first opening 109 formed therein to expose the connection pad 355. For example, the first dielectric layer 101 may include a dielectric adhesive film, such as an Ajinomoto build-up film (ABF). Alternatively, the first dielectric layer 101 may include an organic material, such as, for example, a photo-imageable dielectric (PID) material. The photo-imageable dielectric (PID) material may include one or more of, for example, photosensitive polyimide, polybenzoxazole, phenolic polymers, and benzocyclobutene polymers. When the first dielectric layer 101 is formed of the Ajinomoto build-up film (ABF), the first opening 109 may be formed through a photolithography process and an etching process. When the first dielectric layer 101 is formed of the photo-imageable dielectric (PID) material, the first opening 109 may be formed through a photolithography process and a heat treatment process.

The first redistribution pattern 130 may be formed in the first dielectric layer 101 and on a top surface of the first dielectric layer 101. The first seed pattern 135 may be formed on a bottom surface of the first redistribution pattern 130. The formation of the first seed pattern 135 and the first redistribution pattern 130 may include forming a first seed layer in the first opening 109 and on the top surface of the first dielectric layer 101, forming on the first seed layer a resist pattern that has a guide opening, performing an electroplating process in which the first seed layer is used as an electrode, removing the resist pattern to expose a portion of the first seed layer, and etching the exposed portion of the first seed layer. The guide opening may be spatially connected to the first opening 109. In an example embodiment of the present inventive concept, in a plan view, the first opening 109 may be completely covered by the guide opening.

The electroplating process may form the first redistribution pattern 130 in the first opening 109 and the guide opening. The first redistribution pattern 130 may include a first via part and a first wire part. The first via part may be formed in the first opening 109, and the first wire part may be formed on the first dielectric layer 101. The first via part may have a tapered shape. For example, the first via part may have inclined side surfaces. As shown in FIG. 2G, a width W1 at a bottom surface of the first via part may be smaller than a width W2 at a top surface of the first via part. In this case, the top surface of the first via part may be an imaginary surface located at the same level as that of a bottom surface of the first wire part. The first wire part of the first redistribution pattern 130 may be provided on the top surface of the first via part, and the first wire part and the first via part may be connected with no interface therebetween. For example, the first wire part and the first via part of the first redistribution pattern 130 may be formed by the same electroplating process, and thus may be formed as an integral structure. The first wire part of the first redistribution pattern 130 may have a width greater than the width W2 at the top surface of the first via part. In this description, the phrase “coupled to the first redistribution substrate 100” may mean “coupled to the first redistribution pattern 130.” The first redistribution pattern 130 may be an upper redistribution pattern.

The etching of the first seed layer may form the first seed pattern 135 on the bottom surface of the first redistribution pattern 130. For example, the first seed pattern 135 may be interposed between the connection pad 355 and the first redistribution pattern 130 and between the first dielectric layer 101 and the first redistribution pattern 130. The first seed pattern 135 may be in direct contact with the connection pad 355. The first redistribution pattern 130 may be electrically connected through the first seed pattern 135 to the connection pad 355. In an example embodiment of the present inventive concept, the first redistribution pattern 130 may be a signal pattern, a power pattern and/or a ground pattern, but the present inventive concept is not limited thereto. The first seed pattern 135 may not be in direct contact with a conductive component of the semiconductor chip 500. The first seed pattern 135 may include a material different from that of the first redistribution pattern 130. For example, the first seed pattern 135 may include a conductive seed material. The conductive seed material may include one or more of, for example, copper (Cu), titanium (Ti), and any alloy thereof. The first seed pattern 135 may serve as a barrier layer to prevent diffusion of materials included in the first redistribution pattern 130. The first seed pattern 135 may be an upper seed pattern.

The formation of the first dielectric layer 101 may further be repeatedly performed. Therefore, a plurality of first dielectric layers 101 may be formed. The first dielectric layers 101 may include the same material and may be connected with no interface therebetween.

The formation of the first seed pattern 135 and that of the first redistribution pattern 130 may further be repeatedly performed. In this case, stacked first redistribution patterns 130 may be formed, and first seed patterns 135 may be formed between the first redistribution patterns 130. For brevity, the following will describe a single first seed pattern 135 and a single first redistribution pattern 130.

The first redistribution pad 150 may be formed on an uppermost first dielectric layer 101 and may be coupled to the first redistribution pattern 130. Therefore, the first redistribution pad 150 may be electrically connected through the first redistribution pattern 130 to the second conductive pad 352. The first redistribution pad 150 may include metal, such as, for example, copper (Cu). The first seed pad 155 may be formed on a bottom surface of the first redistribution pad 150. For example, the first seed pad 155 may be formed in an opening exposing the top surface of the first redistribution pattern 130 and on the top surface of the uppermost first dielectric layer 101. According to an example embodiment of the present inventive concept, the first redistribution pad 150 may be formed by performing an electroplating process in which the first seed pad 155 is used as an electrode. The first seed pad 155 may include a conductive seed material. As shown in FIG. 2G, the first redistribution pad 150 may further include a protection pad 151. The protection pad 151 may be exposed on a top surface of the first redistribution pad 150 and may include a material different from that of the first redistribution pad 150. For example, the protection pad 151 may include one or more of, for example, nickel (Ni), gold (Au), and any combination thereof. The protection pad 151 may protect the first redistribution pad 150. For example, the protection pad 151 may contain a material less sensitive to the environment, and thus can be configured to protect the first redistribution pad 150 from external chemical and/or physical damage. In figures except for FIG. 2G, the illustration of the protection pad 151 is omitted for brevity of drawings.

Referring to FIG. 2H, a second carrier substrate 920 may be attached onto a top surface of the first redistribution substrate 100. A second carrier adhesion layer may further be interposed between the first redistribution substrate 100 and the second carrier substrate 920, but the present inventive concept is not limited thereto.

The first carrier substrate 910 may be removed from the molding layer 400, and thus the bottom surface 400b of the molding layer 400 may be exposed. The removal of the first carrier substrate 910 may be preceded by the attachment of the second carrier substrate 920, but the present inventive concept is not limited thereto.

Referring sequentially to FIGS. 2I and 2J, a grinding process may be performed on the bottom surface 400b of the molding layer 400, thereby thinning the molding layer 400. For example, the grinding process may remove the solder patterns 553 and a portion of the molding layer 400. As shown in FIG. 2J, after the grinding process is terminated, the bottom surfaces 551b of the pillar patterns 551 may be exposed, and the bottom surface 352b of the second conductive pad 352 may also be exposed. The grinding process may be terminated after the solder patterns 553 is completely removed and the bottom surface of the second conductive pad 352 is exposed, and thus, in many instances, some portion of the pillar pattern 551 at the bottom part and/or some portion of the second conductive pad 352 at the bottom part may also be removed. The molding layer 400 may have a grinded bottom surface 400b′ coplanar with the bottom surfaces 551b of the pillar patterns 551 and with the bottom surface 352b of the second conductive pad 352. For example, the bottom surface 400b′ of the molding layer 400 may be located at a level substantially the same as that of the bottom surfaces 551b of the pillar patterns 551 and that of the bottom surface 352b of the second conductive pad 352. In the present example embodiment, the grinding process is performed after the first redistribution substrate 100 is formed. However, the present inventive concept is not limited thereto. For example, in an example embodiment of the present inventive concept, the first redistribution substrate 100 is formed after performing the grinding process.

Even when the molding layer 400 is formed to have an undulation on the bottom surface 400b thereof as discussed above in the formation of the molding layer 400 depicted in FIG. 2D, after the grinding process, the bottom surface 400b′ of the molding layer 400 may be substantially flat. Thus, the pillar patterns 551 and the second conductive pads 352 may be satisfactorily coupled to a lower redistribution substrate. Therefore, it may be possible to increase accuracy of a semiconductor package fabricating method and to enhance reliability of a semiconductor package.

Referring to FIG. 2K, a second dielectric layer 201 may be formed on the grinded bottom surface 400b′ of the molding layer 400. The second dielectric layer 201 may include, for example, a photo-imageable dielectric (PID) material. In this case, a coating process may be performed to form the second dielectric layer 201. Alternatively, the second dielectric layer 201 may include an Ajinomoto build-up film (ABF) or a solder resist material. The second dielectric layer 201 may be patterned to form second openings 209 in the second dielectric layer 201. The patterning of the second dielectric layer 201 may be performed by exposure and development processes. For example, when the second dielectric layer 201 is formed of the photo-imageable dielectric (PID) material, the second openings 209 may be formed through a photolithography process and a heat treatment process. When the second dielectric layer 201 is formed of the Ajinomoto build-up film (ABF), the second openings 209 may be formed through a photolithography process and an etching process. The second openings 209 may expose the bottom surfaces 551b of the pillar patterns 551 and the bottom surface 352b of the second conductive pad 352.

A plurality of second redistribution patterns 230 may be formed in the second openings 209 and on a bottom surface of the second dielectric layer 201. Each of the second redistribution patterns 230 may include a second via part and a second wire part. The second via part may be formed in a corresponding second opening 209. A width W3 at a top surface of the second via part may be smaller than a width W4 at a bottom surface of the second via part. The second wire part may be formed on the bottom surface of the second via part, and the second wire part and the second via part may be connected with no interface therebetween. For example, the second wire part and the second via part of the second redistribution patterns 230 may be formed by the same electroplating process to be described, and thus the second wire part and the second via part may be formed as an integral structure. The second wire part may extend onto the bottom surface of the second dielectric layer 201. The second wire part may have a width greater than the width W4 at the bottom surface of the second via part. The bottom surface of the second via part may be an imaginary surface located at substantially the same level as that of a top surface of the second wire part. The second redistribution patterns 230 may include metal, such as, for example, copper (Cu). The second redistribution patterns 230 may be lower redistribution patterns.

A plurality of second seed patterns 235 may be formed on top surfaces of the second redistribution patterns 230. The formation of the second seed patterns 235 may include performing a deposition process to form a second seed layer and patterning the second seed layer. In an example embodiment of the present inventive concept, the deposition process to form the second seed layer may include, for example, a physical vapor deposition (PVD) process, a chemical vapor deposition (CVD) process, or an atomic layer deposition (ALD) process. In an example embodiment of the present inventive concept, the second seed layer may be conformally formed in the second opening 209 and on the bottom surface of the second dielectric layer 201. The second seed patterns 235 may be interposed between the second redistribution patterns 230 and the pillar patterns 551 and between the second redistribution patterns 230 and the second dielectric layer 201. Each of the second seed patterns 235 may be in direct contact with a corresponding one of the bottom surfaces 551b of the pillar pattern 551 and the bottom surface 352b of the second conductive pad 352. The second seed patterns 235 may include a material different from that of the second redistribution patterns 230. For example, the second seed patterns 235 may include a conductive seed material. The second seed patterns 235 may each serve as a barrier layer to prevent diffusion of materials included in a corresponding one of the second redistribution patterns 230. The second seed patterns 235 may be lower seed patterns.

The second redistribution patterns 230 may be formed by an electroplating process in which the second seed patterns 235 are used as an electrode.

According to an example embodiment of the present inventive concept, before the formation of the second dielectric layer 201, the pillar patterns 551 and the second conductive pad 352 may be inspected to obtain their arrangement positions. The inspection result may be reflected to adjust formation positions of the second openings 209, the second seed patterns 235, and the second redistribution patterns 230. Accordingly, it may be possible to increase accuracy of a semiconductor package fabricating method and to enhance reliability of a semiconductor package.

Referring to FIG. 2L, the formation of the second dielectric layer 201, the formation of the second seed patterns 235, and the formation of the second redistribution patterns 230 may further be repeatedly performed. Therefore, there may be formed a plurality of stacked second dielectric layers 201, a plurality of stacked second seed patterns 235, and a plurality of stacked second redistribution patterns 230. The plurality of second seed patterns 235 and the plurality of second redistribution patterns 230 may be alternately stacked. The second dielectric layers 201 may include the same material, and no distinct interface may be provided between the second dielectric layers 201. The second redistribution patterns 230 may include second lower redistribution patterns 230L and second upper redistribution patterns 230U on the second lower redistribution patterns 230L. The second seed patterns 235 may further be correspondingly interposed between the second lower redistribution patterns 230L and the second upper redistribution patterns 230U. Although two second seed patterns 235 and two second redistribution patterns 230 are shown in FIG. 2L as an example, the present inventive concept is not limited thereto. For example, in an example embodiment of the present inventive concept, three or more second seed patterns 235 and three or more second redistribution patterns 230 may be included in a second redistribution substrate 200.

The second redistribution pads 250 may be correspondingly formed on bottom surfaces of the second lower redistribution patterns 230L and may be correspondingly coupled to the second lower redistribution patterns 230L. The second redistribution pads 250 may be formed in a lowermost second dielectric layer 201 and on a bottom surface of the lowermost second dielectric layer 201. A plurality of second seed pads 255 may be correspondingly formed on top surfaces of the second redistribution pads 250. To form the second seed pads 255, the lowermost second dielectric layer 201 may be patterned to form openings to expose bottom surfaces of the second lower redistribution patterns 230L, then a seed pad layer may be formed in the openings and on the bottom surface of the lowermost second dielectric layer 201 and patterned to form the second seed pads 255. For example, the second seed pads 255 may be interposed between the second redistribution pads 250 and the second lower redistribution patterns 230L and between the second redistribution pads 250 and the lowermost second dielectric layer 201. Accordingly, a second redistribution substrate 200 may be eventually fabricated.

The second redistribution substrate 200 may include the second dielectric layer 201, the second seed patterns 235, the second redistribution patterns 230, the second seed pads 255, and the second redistribution pads 250. The second redistribution substrate 200 may be a lower redistribution substrate. When the second redistribution substrate 200 is a lower redistribution substrate, the second seed patterns 235 may be lower seed patterns and the second redistribution patterns 230 may be lower redistribution patterns. The semiconductor chip 500 may be coupled through the second redistribution substrate 200 to the connection substrate 300. The phrase “coupled to the second redistribution substrate 200” may mean “coupled to at least one of the second redistribution patterns 230.” The pillar patterns 551 may be correspondingly provided on the bottom surfaces of the chip pads 530, thereby being coupled to the chip pads 530 of the semiconductor chip 500. Each of the second seed patterns 235 of the second redistribution substrate 200 may be in direct contact with a corresponding one of the pillar pattern 551. Accordingly, various functions of the chip pads 530 of the semiconductor chip 500 may be redistributed by the second redistribution substrate 200.

Differently from that discussed above, neither the second seed patterns 235 nor the second redistribution patterns 230 may be repeatedly formed. In this case, the second lower redistribution patterns 230L may be omitted, and the second redistribution pads 250 may be formed on bottom surfaces of the second upper redistribution patterns 230U and may be correspondingly coupled to the second upper redistribution patterns 230U.

Referring to FIG. 2M, solder balls 600 may be formed on a bottom surface of the second redistribution substrate 200. For example, the solder balls 600 may be attached onto bottom surfaces of the second redistribution pads 250. The solder balls 600 may be coupled through the second redistribution substrate 200 to either the semiconductor chip 500 or the connection substrate 300. The solder balls 600 may include one or more of, for example, tin (Sn), silver (Ag), zinc (Zn), lead (Pb), and any alloy thereof. The solder balls 600 may be coupled to an external device. For example, the external device may be electrically connected to the second redistribution substrate 200 through the solder balls 600. The aforementioned processes may fabricate a semiconductor package 10. The semiconductor package 10 may include the first redistribution substrate 100, the second redistribution substrate 200, the solder balls 600, the semiconductor chip 500, the pillar patterns 551, the connection substrate 300, the first conductive pad 351, the second conductive pad 352, and the molding layer 400. The semiconductor package 10 may be a lower package.

Each of the molding layer 400 and the adhesion layer may have thermal conductivity less than that of the semiconductor chip 500. When the adhesion layer or the molding layer 400 is interposed between the semiconductor chip 500 and the first redistribution substrate 100, it may be difficult to discharge heat generated from the semiconductor chip 500. For example, due to the low thermal conductivity of the adhesion layer or the molding layer 400 interposed therebetween, the semiconductor chip 500 may decrease in thermal radiation properties. According to an example embodiment of the present inventive concept, as the top surface 500a of the semiconductor chip 500 is directly in physical/thermal contact with the first redistribution substrate 100, the semiconductor chip 500 may enhance in thermal radiation properties.

The molding layer 400 may have a coefficient of thermal expansion (CTE) greater than that of the semiconductor chip 500 or that of the connection substrate 300. For example, the CTE of the molding layer 400 may be greater than that of the semiconductor substrate (see 510 of FIG. 2C) of the semiconductor chip 500. According to an example embodiment of the present inventive concept, the molding layer 400 may have a relatively small thickness. For example, because the molding layer 400 is formed on the bottom surface of the temporary tape 900 as discussed above with reference to FIG. 2D, the molding layer 400 may not extend onto the top surface 500a of the semiconductor chip 500, and may be thinned by the grinding process discussed in FIGS. 2I and 2J. Therefore, there may be a reduction in coefficient of thermal expansion between the molding layer 400 and the semiconductor chip 500 or between the molding layer 400 and the connection substrate 300, and as a result, the semiconductor package 10 may be prevented from warpage. For example, when the molding layer 400 has a smaller thickness, the change in dimension may be smaller when there is a change in temperature, and thus the semiconductor package 10 may be prevented from warpage.

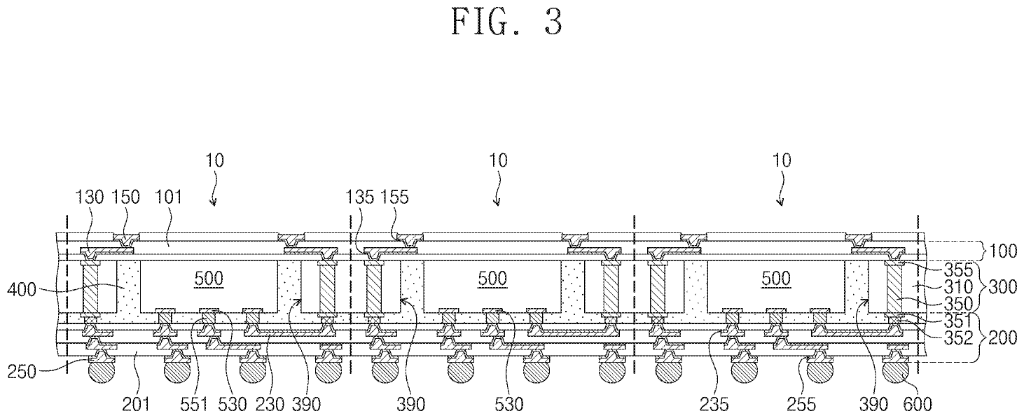

FIG. 3 illustrates a cross-sectional view showing a method of fabricating a semiconductor package according to an example embodiment of the present inventive concept.

Referring to FIG. 3, a connection substrate 300 may be prepared in a panel level or a wafer level. A first conductive pad 351 and a second conductive pad 352 may be provided on a bottom surface of the connection substrate 300. The connection substrate 300 may be similar to that discussed in the example embodiment of FIGS. 1 and 2A. In contrast, the connection substrate 300 may have a plurality of holes 390. A plurality of semiconductor chips 500 may be correspondingly provided in the holes 390 of the connection substrate 300 and may be disposed laterally spaced apart from the connection substrate 300. For example, each of the semiconductor chips 500 may be placed side by side with the connection substrate 300 in a corresponding one of the holes 390. Each of the semiconductor chips 500 may be the same as that discussed in the example embodiments of FIGS. 2B and 2C. The semiconductor chips 500 may be provided with pillar patterns 551 on bottom surfaces thereof. Solder patterns (see 553 of FIG. 2B) may further be provided on bottom surfaces 551b of the pillar patterns 551. A grinding process may be performed to remove the solder patterns 553. The grinding process may be substantially the same as that discussed in the example embodiments of FIGS. 2I and 2J. The pillar patterns 551 may remain after the grinding process.

There may be formed a molding layer 400, a first redistribution substrate 100, a second redistribution substrate 200, and solder balls 600. The formation of the molding layer 400, the first redistribution substrate 100, the second redistribution substrate 200, and the solder balls 600 may be substantially the same as that discussed in the embodiments of FIGS. 2D to 2M. In contrast, the molding layer 400, the first redistribution substrate 100, and the second redistribution substrate 200 may be formed in a panel level or a wafer level. For example, instead of the semiconductor chip 500 being molded with the molding layer 400 within the hole 390 in a printed circuit board (PCB), the connection substrate 300 may be prepared in a panel level or a wafer level with the semiconductor chips 500 being molded with the molding layer 400 embedded within the holes 390 in a wafer or in a panel.

The first redistribution substrate 100, the molding layer 400, and the second redistribution substrate 200 may be diced along dash-dot lines, and thus a plurality of semiconductor packages 10 may be separated from each other. The semiconductor package 10 may be fabricated in a panel level or a wafer level. For example, a wafer or a panel including the first redistribution substrate 100, the molding layer 400, and the second redistribution substrate 200 may be sawed or cut along the dash-dot lines using a blade or laser. As a result, separated semiconductor packages 10 are formed. Each of the semiconductor packages 10 may be the same as that discussed in the example embodiment of FIG. 2M. Therefore, as shown in FIG. 2M, each of the separated semiconductor packages 10 may be configured such that an outer sidewall of the connection substrate 300 may be vertically aligned with that of the molding layer 400, that of the first redistribution substrate 100, and that of the second redistribution substrate 200. The connection substrate 300 may have a width substantially the same as that of the molding layer 400, that of the first redistribution substrate 100, and that of the second redistribution substrate 200.

Except the example embodiment of FIG. 3, the following will discuss a single semiconductor package 10 for brevity of description, but methods of fabricating semiconductor packages of the present inventive concept are not limited to chip-level fabrication.

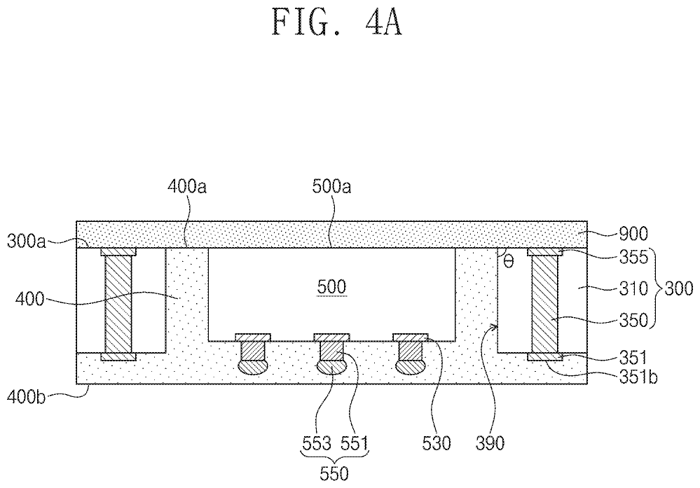

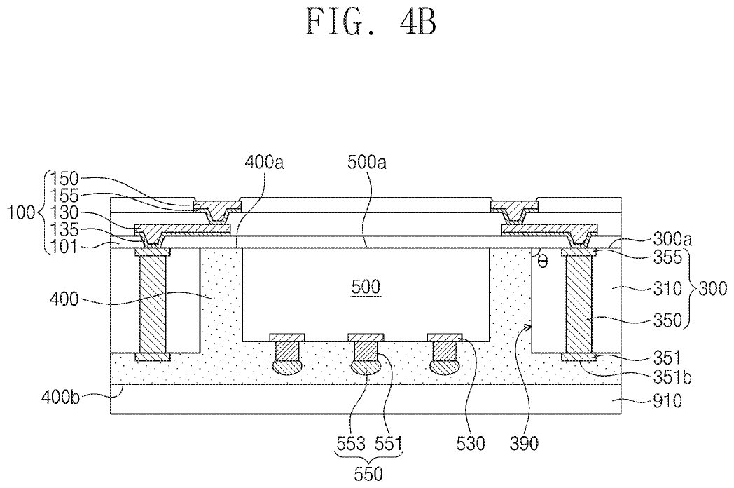

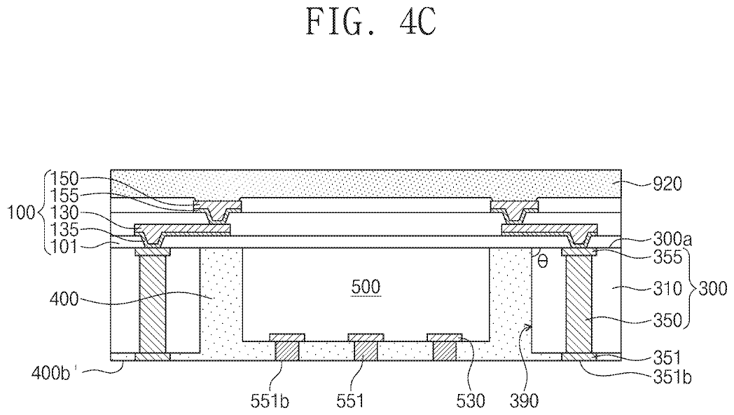

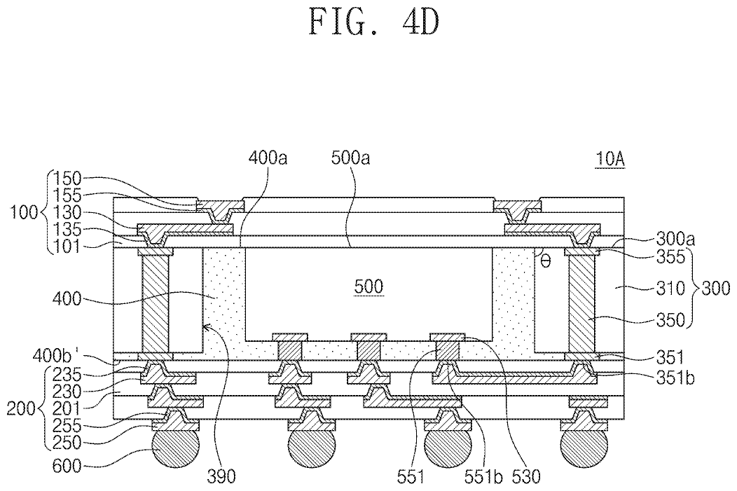

FIGS. 4A to 4C illustrate cross-sectional views taken along line I-II of FIG. 1, showing a method of fabricating a semiconductor package according to an example embodiment of the present inventive concept. A duplicate description will be omitted below.

Referring to FIG. 4A, a connection substrate 300, which is provided with a first conductive pad 351, may be prepared. The connection substrate 300 and the first conductive pad 351 may be substantially the same as those discussed in the example embodiment of FIGS. 1 and 2A. For example, the connection substrate 300 may include a base layer 310, a connection via 350, and a connection pad 355. The first conductive pad 351 may be provided on a bottom surface of the connection substrate 300. However, the second conductive pad 352 of FIG. 2A may not be provided. The connection substrate 300 may be disposed on a bottom surface of a temporary tape 900, and a top surface 300a of the connection substrate 300 may be in contact with the temporary tape 900.

A semiconductor chip 500, which is provided with bumps 550, may be prepared. The bumps 550 may include pillar patterns 551 and solder patterns 553. The semiconductor chip 500 and the bumps 550 may be substantially the same as those discussed in the example embodiment of FIGS. 2B and 2C. The semiconductor chip 500 may be directly disposed on the temporary tape 900, and a top surface 500a of the semiconductor chip 500 may be in physical contact with the bottom surface of the temporary tape 900, and no adhesion layer may be separately provided between the temporary tape 900 and the semiconductor chip 500. Accordingly, the process accuracy may increase and the fabrication process may be simplified. In this case, the semiconductor chip 500 may be provided within a hole 390 of the connection substrate 300 and may be disposed laterally spaced apart from the connection substrate 300. The width at an upper portion of the hole 390 may be the same as or similar to that at a lower portion of the hole 390, such that the semiconductor chip 500 may be satisfactorily accommodated in the hole 390.

A molding layer 400 may be formed on the bottom surface of the connection substrate 300 and on a bottom surface of the semiconductor chip 500, thereby covering a bottom surface 351b of the first conductive pad 351 and bottom surfaces of the bumps 550. The molding layer 400 may extend into a gap between the connection substrate 300 and the semiconductor chip 500, thereby contacting the bottom surface of the temporary tape 900. The first conductive pad 351, the pillar pattern 551 and the solder pattern 553 may be completely surrounded by the molding layer 400.

Afterwards, the temporary tape 900 may be removed to expose a top surface 400a of the molding layer 400, the top surface 500a of the semiconductor chip 500, and the top surface 300a of the connection substrate 300.

Referring to FIG. 4B, a first carrier substrate 910 may be disposed on a bottom surface 400b of the molding layer 400. A first redistribution substrate 100 may be formed on and directly in physical contact with the top surface 400a of the molding layer 400, the top surface 500a of the semiconductor chip 500, and the top surface 300a of the connection substrate 300. Since no adhesion layer is interposed therebetween to cause the semiconductor chip 500 to decrease in thermal radiation properties, as the top surface 500a of the semiconductor chip 500 is directly in physical/thermal contact with the first redistribution substrate 100, the semiconductor chip 500 may enhance in thermal radiation properties. The first redistribution substrate 100 may include a first dielectric layer 101, a first seed pattern 135, a first redistribution pattern 130, a first seed pad 155, and a first redistribution pad 150. The first redistribution substrate 100 may be formed by substantially the same method discussed in the example embodiments of FIGS. 2F and 2G.

Referring to FIG. 4C, the first carrier substrate 910 may be removed to expose the bottom surface 400b of the molding layer 400. A second carrier substrate 920 may be attached to a top surface of the first redistribution substrate 100.

A grinding process may be performed on the exposed bottom surface 400b of the molding layer 400. The grinding process may be performed substantially identically to that discussed in the example embodiments of FIGS. 2I and 2J. For example, the grinding process may remove the solder patterns 553 and a portion of the molding layer 400. However, after the grinding process is terminated, bottom surfaces 551b of the pillar patterns 551 may be exposed, and a bottom surface 351b of the first conductive pad 351 may also be exposed. The molding layer 400 may have a grinded bottom surface 400b′ coplanar with the bottom surfaces 551b of the pillar patterns 551 and with the bottom surface 351b of the first conductive pad 351. Even when the molding layer 400 is formed to have an undulation on the bottom surface 400b thereof, after the grinding process, the grinded bottom surface 400b′ of the molding layer 400 may be substantially flat. Thus, the pillar patterns 551 and the first conductive pad 351 may be satisfactorily coupled to a lower redistribution substrate. Therefore, it may be possible to increase accuracy of a semiconductor package fabricating method and to enhance reliability of a semiconductor package.

Referring to FIG. 4D, a second redistribution substrate 200 may be formed on the grinded bottom surface 400b′ of the molding layer 400. The second redistribution substrate 200 may be formed by substantially the same method discussed in the example embodiments of FIGS. 2K and 2L. The second redistribution substrate 200 may include a second dielectric layer 201, second seed patterns 235, second redistribution patterns 230, second seed pads 255, and second redistribution pads 250. However, at least one of the second seed patterns 235 may be in direct contact with the bottom surface 351b of the first conductive pad 351. Other ones of the second seed patterns 235 may be in contact with the bottom surfaces 551b of the pillar patterns 551. The formation of the second dielectric layer 201, the formation of the second seed patterns 235, and the formation of the second redistribution patterns 230 may further be repeatedly performed. Therefore, a plurality of stacked second dielectric layers 201, a plurality of stacked second seed patterns 235, and a plurality of stacked second redistribution patterns 230 may be formed. A plurality of solder balls 600 may be formed on a bottom surface of the second redistribution substrate 200 and may be coupled to the second redistribution pads 250. Accordingly, a semiconductor package 10A may be eventually fabricated.

The semiconductor package 10A may include the first redistribution substrate 100, the second redistribution substrate 200, the solder balls 600, the semiconductor chip 500, the pillar patterns 551, the connection substrate 300, the first conductive pad 351, and the molding layer 400. The semiconductor package 10A may be a lower package.

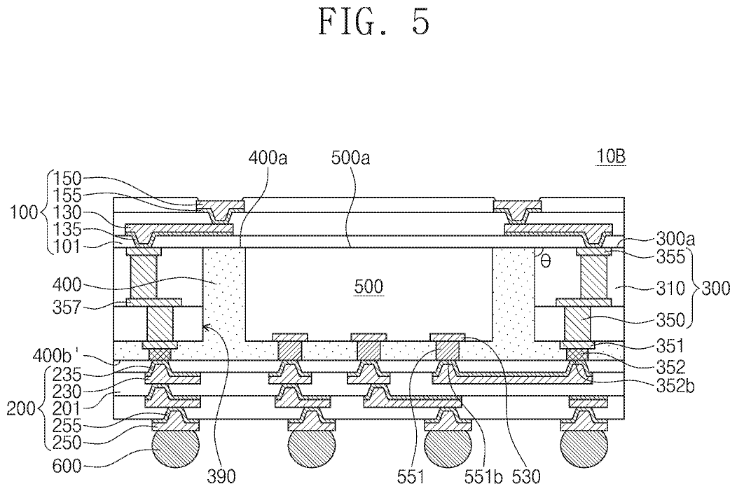

FIG. 5 illustrates a cross-sectional view taken along line I-II of FIG. 1, showing a semiconductor package according to an example embodiment of the present inventive concept.

Referring to FIG. 5, a semiconductor package 10B may include a first redistribution substrate 100, a second redistribution substrate 200, solder balls 600, a semiconductor chip 500, pillar patterns 551, a connection substrate 300, a first conductive pad 351, a second conductive pad 352, and a molding layer 400. The semiconductor package 10B may be a lower package.

The connection substrate 300 may include a plurality of base layers 310, a plurality of connection vias 350, a conductive pattern 357, and a connection pad 355. The base layers 310 may be stacked. Each of the base layers 310 may be substantially the same as or similar to the base layer 310 discussed in the example embodiment of FIG. 2A. The connection vias 350 may correspondingly penetrate the base layers 310. The conductive pattern 357 may be interposed between and coupled to the connection vias 350. The connection pad 355 may be disposed on a top surface 300a of the connection substrate 300 and may be coupled to the first conductive pad 351 through the connection vias 350 and the conductive pattern 357. In this case, a top surface of the connection pad 355 is a part of the top surface 300a of the connection substrate 300. The number of the stacked base layers 310 and of the stacked connection vias 350 may be variously changed.

A large number of methods may be employed to fabricate the semiconductor package 10B. For example, the semiconductor package 10B may be fabricated by substantially the same method discussed in the example embodiments of FIGS. 2A to 2M. Alternatively, the semiconductor package 10B may be fabricated by the method discussed in the example embodiments of FIGS. 4A to 4D. In this case, the second conductive pad 352 may be omitted, and the first conductive pad 351 may be in direct contact with a corresponding second seed pattern 235.

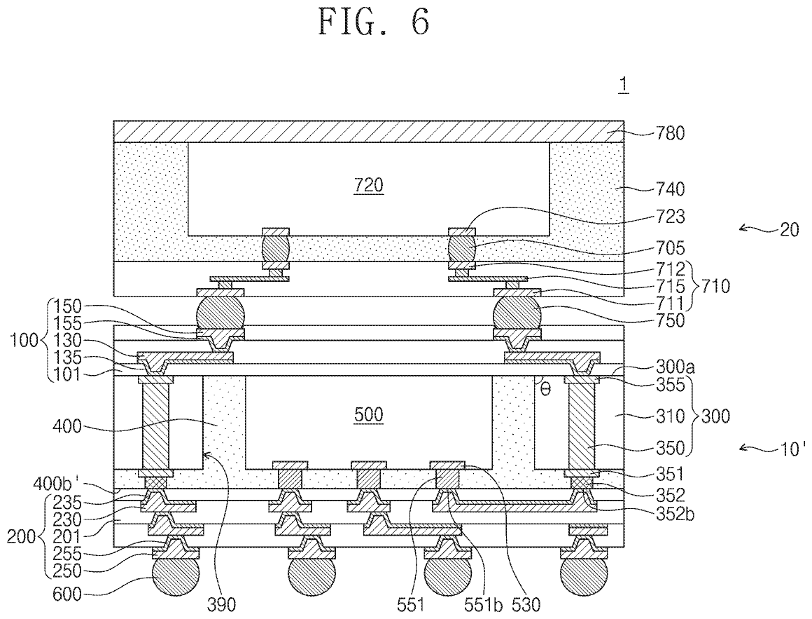

FIG. 6 illustrates a cross-sectional view showing a semiconductor package according to an example embodiment of the present inventive concept.

Referring to FIG. 6, a semiconductor package 1 may include a lower package 10′, an upper package 20, and a connection solder ball 750. The lower package 10′ may be substantially the same as the semiconductor package 10 discussed in the example embodiment of FIG. 2M. For example, the lower package 10′ may include a first redistribution substrate 100, a second redistribution substrate 200, solder balls 600, a semiconductor chip 500, pillar patterns 551, a connection substrate 300, a first conductive pad 351, a second conductive pad 352, and a molding layer 400. Alternatively, the lower package 10′ may be substantially the same as the semiconductor package 10A of FIG. 4D or the semiconductor package 10B of FIG. 5.

The upper package 20 may include an upper substrate 710, an upper semiconductor chip 720, an upper bump 705, and an upper molding layer 740. The upper substrate 710 may be disposed to be spaced apart from a top surface of the first redistribution substrate 100. The upper substrate 710 may be a printed circuit board (PCB) or a redistribution layer. A first metal pad 711 and a second metal pad 712 may be disposed respectively on a bottom surface and a top surface of the upper substrate 710. The upper substrate 710 may be provided therein with a metal line 715 coupled to the first metal pad 711 and the second metal pad 712.

The upper semiconductor chip 720 may be mounted on the top surface of the upper substrate 710. The upper semiconductor chip 720 may be of a different type from the semiconductor chip 500. For example, the upper semiconductor chip 720 may be a memory chip, and the semiconductor chip 500 may be a logic chip. The upper package 20 may include several stacked memory chips instead of just one upper semiconductor chip 720, and the stacked memory chips may be electrically coupled to each other through, for example, wire bonds or through vias. The upper bump 705 may be interposed between the upper substrate 710 and the upper semiconductor chip 720, and may be coupled to the second metal pad 712 and a chip pad 723 of the upper semiconductor chip 720. The upper bump 705 may include a solder material. The upper molding layer 740 may be provided on the upper substrate 710 and may cover a sidewall of the upper semiconductor chip 720. The upper molding layer 740 may further extend onto a bottom surface of the upper semiconductor chip 720 and may further encapsulate the upper bump 705.

The connection solder ball 750 may be interposed between the first redistribution substrate 100 and the upper substrate 710, thereby being coupled to the first redistribution pad 150 and the first metal pad 711. Therefore, the connection solder ball 750 may be used to connect the upper package 20 to the lower package 10′. The connection solder ball 750 may electrically and mechanically couple the upper package 20 to the lower package 10′, and may be replaced with any other suitable electrical and mechanical coupling structure. The connection solder ball 750 may include a solder material, such as one or more of, for example, tin (Sn), silver (Ag), zinc (Zn), lead (Pb), and any alloy thereof.

The upper package 20 may further include a thermal radiation structure 780. The thermal radiation structure 780 may be disposed on a top surface of the upper semiconductor chip 720 and on a top surface of the upper molding layer 740. The thermal radiation structure 780 may further extend onto a lateral surface of the upper molding layer 740. The thermal radiation structure 780 may include a heat sink, a heat slug, or a thermal interface material (TIM) layer. The thermal radiation structure 780 may include, for example, metal.

According to the present inventive concept, a top surface of a semiconductor chip may be attached without an adhesion layer to a temporary tape. Therefore, accuracy of semiconductor package fabrication methods may increase, and the semiconductor package fabricating methods may be simplified. After removal of the temporary tape, a first redistribution substrate may be directly formed on a top surface of the semiconductor chip. A semiconductor package may increase in thermal properties.

This detailed description of the present inventive concept should not be construed as limited to the example embodiments set forth herein, and it is intended that the present inventive concept covers the various combinations, the modifications and variations of this inventive concept without departing from the spirit and scope of the present inventive concept. Some example embodiments of the present inventive concept may be combined with each other.

1. A method of fabricating a semiconductor package, the method comprising:
preparing a semiconductor chip provided with a pillar pattern on a bottom surface of the semiconductor chip;
placing the semiconductor chip side by side with a connection substrate provided with a conductive pad on a bottom surface of the connection substrate;
forming a molding layer on the bottom surface of the connection substrate and on the bottom surface of the semiconductor chip to cover the pillar pattern and the conductive pad;
forming a first redistribution substrate on a top surface of the connection substrate, a top surface of the semiconductor chip, and a top surface of the molding layer, the first redistribution substrate being directly in physical contact with the top surface of the semiconductor chip; and
performing a grinding process on a bottom surface of the molding layer to expose the pillar pattern and the conductive pad,
wherein an outer sidewall of the connection substrate is vertically aligned with an outer sidewall of the first redistribution substrate.

2. The method of claim 1, wherein the forming of the first redistribution substrate is performed after the performing of the grinding process.

3. The method of claim 1, further comprising forming a second redistribution substrate on a bottom surface of the exposed pillar pattern and on a bottom surface of the exposed conductive pad.

4. The method of claim 3, wherein the second redistribution substrate includes:
a plurality of second seed patterns directly coupled to the pillar pattern and the conductive pad; and
a plurality of second redistribution patterns formed on bottom surfaces of the plurality of second seed patterns.

5. The method of claim 1, wherein the first redistribution substrate includes:
a first seed pattern directly coupled to a connection pad of the connection substrate; and
a first redistribution pattern formed on the first seed pattern,
wherein the connection pad of the connection substrate is on the top surface of the connection substrate.

6. The method of claim 1, further comprising:
allowing a temporary tape to be directly attached to the semiconductor chip and the connection substrate; and
after the forming of the molding layer, removing the temporary tape to expose the top surface of the connection substrate and the top surface of the semiconductor chip.

7. The method of claim 1, wherein the first redistribution substrate is directly in physical contact with the top surface of the connection substrate and with the top surface of the molding layer.

8. The method of claim 1, wherein
the molding layer extends between the connection substrate and the semiconductor chip, and
the top surface of the molding layer is coplanar with the top surface of the connection substrate and with the top surface of the semiconductor chip.

9. The method of claim 1, wherein
the connection substrate has a hole,
the placing of the semiconductor chip side by side with the connection substrate includes providing the semiconductor chip in the hole of the connection substrate, and
an angle between the top surface of the connection substrate and a sidewall of the hole is in a range from about 85 degrees to about 95 degrees.

10. A method of fabricating a semiconductor package, the method comprising:
preparing a semiconductor chip provided with a bump on a bottom surface of the semiconductor chip, the bump including a pillar pattern;
placing the semiconductor chip side by side with a connection substrate provided with a conductive pad on a bottom surface of the connection substrate;
forming a molding layer on the bottom surface of the connection substrate and on the bottom surface of the semiconductor chip to cover the bump and the conductive pad;
forming a first redistribution substrate in physical contact with a top surface of the connection substrate, a top surface of the semiconductor chip, and a top surface of the molding layer; and
performing a grinding process on a bottom surface of the molding layer to expose the pillar pattern and the conductive pad,
wherein the connection substrate includes a plurality of connection pads on the top surface of the connection substrate, and
wherein the forming of the first redistribution substrate includes:
forming a first seed pattern directly coupled to each of the plurality of connection pads; and
forming a first redistribution pattern on the first seed pattern.

11. The method of claim 10, wherein
the bump further includes a solder pattern on a bottom surface of the pillar pattern, and
the performing of the grinding process includes removing the solder pattern.

12. The method of claim 10, wherein a width of the connection substrate is substantially the same as a width of the first redistribution substrate.

13. The method of claim 10, further comprising forming a second redistribution substrate,
wherein the forming of the second redistribution substrate includes:
forming a plurality of second seed patterns in direct contact with the exposed pillar pattern and the exposed conductive pad; and
forming a plurality of second redistribution patterns on bottom surfaces of the plurality of second seed patterns.

14. The method of claim 10, further comprising allowing a temporary tape to be directly attached to the top surface of the semiconductor chip and to the top surface of the connection substrate.

15. The method of claim 14, wherein the forming of the molding layer further includes allowing the molding layer to extend between the connection substrate and the semiconductor chip and to contact the temporary tape.

16. A method of fabricating a semiconductor package, the method comprising:
preparing a semiconductor chip provided with a bump on a bottom surface of the semiconductor chip, the bump including a pillar pattern;
preparing a connection substrate provided with a conductive pad on a bottom surface of the connection substrate, the connection substrate having a hole that penetrates the connection substrate;
placing the semiconductor chip and the connection substrate on a bottom surface of a temporary tape, the semiconductor chip being in the hole of the connection substrate and being in physical contact with the bottom surface of the temporary tape;
forming a molding layer on the bottom surface of the connection substrate and on the bottom surface of the semiconductor chip to cover a bottom surface of the bump and a bottom surface of the conductive pad, the molding layer extending between the connection substrate and the semiconductor chip and physically contacting the temporary tape;
removing the temporary tape to expose a top surface of the connection substrate, a top surface of the semiconductor chip, and a top surface of the molding layer;
forming a first redistribution substrate on the top surface of the connection substrate, the top surface of the semiconductor chip, and the top surface of the molding layer, the first redistribution substrate being directly in physical contact with the top surface of the semiconductor chip;
performing a grinding process on a bottom surface of the molding layer to expose the pillar pattern and the conductive pad;
forming a second redistribution substrate on the exposed pillar pattern and the exposed conductive pad; and
forming a solder ball on a bottom surface of the second redistribution substrate.

17. The method of claim 16, wherein
the bump further includes a solder pattern on a bottom surface of the pillar pattern, and
the performing of the grinding process includes removing the solder pattern.

18. The method of claim 16, wherein the forming of the first redistribution substrate includes:
forming a first dielectric layer that covers the top surface of the connection substrate, the top surface of the semiconductor chip, and the top surface of the molding layer;
forming a first seed pattern in the first dielectric layer to contact a connection pad of the connection substrate; and
forming a first redistribution pattern on the first seed pattern,
wherein the connection pad is on the top surface of the connection substrate.

19. The method of claim 16, wherein the forming of the second redistribution substrate includes:
forming a second dielectric layer that covers a grinded bottom surface of the molding layer;
forming a plurality of second seed patterns in physical contact with a bottom surface of the exposed pillar pattern and with the bottom surface of the exposed conductive pad; and
forming a plurality of second redistribution patterns on bottom surfaces of the plurality of second seed patterns.

20. The method of claim 16, wherein
the hole of the connection substrate exposes an inner sidewall of the connection substrate, and
an angle between the inner sidewall and the top surface of the connection substrate is in a range from about 85 degrees to about 95 degrees.

21-22. (canceled)
